(19) United States
(12) Patent Application Publication
(10) Pub. No.: US 2015/0345014 A1
(43) Pub. Date: Dec. 3, 2015

(54) BARRIER LAMINATE AND GAS BARRIER FILM

(71) Applicant: FUJIFILM Corporation, Tokyo (JP)

(72) Inventors: Akiko HATTORI, Ashigarakami-gun (JP); Hiroshi KAWAKAMI, Ashigarakami-gun (JP); Atsushi MUKAI, Ashigarakami-gun (JP)

(73) Assignee: FUJIFILM CORPORATION, Tokyo (JP)

(21) Appl. No.: 14/822,635

(22) Filed: Aug. 10, 2015

Related U.S. Application Data
(63) Continuation of application No. PCT/JP2014/054199, filed on Feb. 21, 2014.

(30) Foreign Application Priority Data
Mar. 7, 2013 (JP) 2013-044947

(51) Int. Cl. C23C 16/34; C23C 16/44; B32B 27/36; B32B 27/08; B32B 27/32

(52) U.S. Cl. CPC C23C 16/345; B32B 27/08; B32B 27/32; B32B 27/36; C23C 16/44; B32B 2307/7244; B32B 2307/7246; B32B 2457/20

(57) ABSTRACT

A barrier laminate includes at least one organic layer and at least one inorganic layer, the organic layer is a layer formed of a polymerizable composition including a polymerizable compound, and the polymerizable compound has a condensed polycyclic hydrocarbon structure. A gas barrier film includes a polymer, in which the barrier laminate is provided on a support and the support includes a cyclic olefin as a repeating unit structure.

### CROSS-REFERENCE TO RELATED APPLICATIONS

This application is a Continuation of PCT International Application No. PCT/JP2014/054199 filed on Feb. 21, 2014, which claims priority under 35 U.S.C §119(a) to Japanese Patent Application No. 2013-044947 filed on Mar. 7, 2013. Each of the above applications is hereby expressly incorporated by reference, in its entirety, into the present application.

### BACKGROUND OF THE INVENTION

1. Field of the Invention

The present invention relates to a barrier laminate and a gas barrier film including the barrier laminate. In addition, the present invention relates to an organic electronic device for image display including the gas barrier film.

2. Description of the Related Art

The use of a gas barrier film as a film shielding moisture, oxygen, and the like has been proposed for the sealing and the like of an organic electronic device (for example, JP2010-228446A and JP2012-213938A). Due to its light weight and flexibility, the gas barrier film has wide applications and, furthermore, the cost reduction can be expected since the gas barrier film can be produced using a roll to roll method.

### SUMMARY OF THE INVENTION

An object of the present invention is to provide a barrier laminate and a gas barrier film which have high barrier properties. In a gas barrier film having a constitution in which a barrier laminate including organic layers and inorganic layers is provided on a plastic film that is a support, the adhesiveness between the support and the barrier laminator may have an influence on the barrier properties. Another object of the present invention is to provide a barrier laminate having high barrier properties when being used in combination with a plastic film that is ordinarily used as a support having low birefringence.

In the process of studies regarding the above-described objects, the present inventors found a constitution of a barrier laminate that is highly adhesive to the plastic film and completed the present invention on the basis of the finding.

That is, the present invention provides the following (1) to (13).

(1) A barrier laminate including at least one organic layer and at least one inorganic layer, in which the organic layer is a layer formed of a polymerizable composition including a polymerizable compound and the polymerizable compound includes 50% by mass or more of a condensed polycyclic hydrocarbon structure with respect to the total amount of polymerizable compounds.

(2) The barrier laminate according to (1), in which the inorganic layer includes a metallic oxide or a metallic nitride.

(3) The barrier laminate according to (1) or (2), in which the inorganic layer includes a silicon compound or an aluminum compound.

(4) The barrier laminate according to any one of (1) to (3), in which the polymerizable compound is a compound represented by General Formula (1) described below.

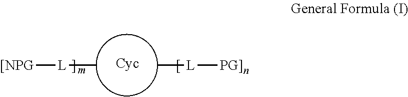

in the formula, Cyc represents a condensed polycyclic hydrocarbon residue, each of L's independently represents a single bond or a divalent linking group, PG represents a polymerizable group, in a case in which multiple PGs are present, each of the PGs independently represents a polymerizable group, NPG represents a non-polymerizable group, in a case in which multiple NPGs are present, each of the NPGs independently represents a non-polymerizable group, n is an integer selected from 1 to 4, and m is an integer selected from 0 to 4.

(5) The barrier laminate according to (4), in which, in General Formula (1), n-L-PG groups are all bonded to one ring in the condensed polycyclic hydrocarbon structure.

(6) The barrier laminate according to (4) or (5), in which the condensed polycyclic hydrocarbon residue is a residue obtained by removing (m+n) hydrogen atoms from any of condensed polycyclic hydrocarbons described below,

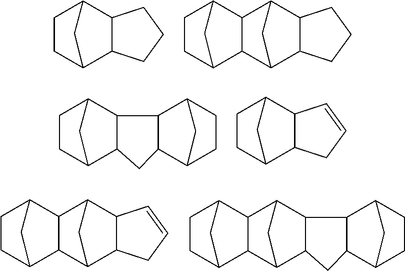

(7) The barrier laminate according to (4) or (5), in which the condensed polycyclic hydrocarbon residue is a residue obtained by removing (m+n) hydrogen atoms from any of condensed polycyclic hydrocarbons described below.

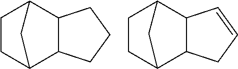

(8) The barrier laminate according to any one of (1) to (7), in which the inorganic layer is formed by chemical vapor deposition (CVD).

(9) A gas barrier film including a polymer, including: a support; and the barrier laminate according to any one of (1) to (8) provided on a support, in which the support includes a cyclic olefin as a repeating unit structure.

(10) The gas barrier film according to claim 9), in which the support is in direct contact with at least one organic layer.

(11) A device, including the gas barrier film according to (9) or (10) which is used as a substrate.

(12) A device sealed using the gas barrier film according to (9) or (10).

(13) The device according to (11) or (12), including an image display element.

From the present invention, an object is to provide a barrier laminate and a gas barrier film which have high barrier properties. Particularly, the present invention provides a barrier laminate having high barrier properties even when being used in combination with a support having low birefringence.

### DESCRIPTION OF THE PREFERRED EMBODIMENTS

Hereinafter, the contents of the present invention will be described in detail.

In the present specification, “to” used to express numerical ranges will be used with a meaning that numerical values before and after the “to” are included in the numerical ranges as the lower limit value and the upper limit value. In addition, in the present invention, an organic EL element refers to an organic electroluminescence element. In the present specification, “(meth)acrylates” will be used to indicate both acrylates and methacrylates.

(Barrier Laminate)

The barrier laminate includes at least one organic layer and at least one inorganic layer and may include two or more organic layers and two or more inorganic layers that are alternatively laminated with each other.

In addition, the barrier laminate may include a so-called gradient material layer in which the composition of the barrier laminate continuously changes in an organic region and an inorganic region in the film thickness direction within the scope of the gist of the present invention. Examples of the gradient material include the material described in a thesis by Kimura “Journal of Vacuum Science and Technology A Vol. 23, pp. 971 to 977 (2005, American Vacuum Society)”, the continuous layer having no interface between an organic region and an inorganic region as disclosed by the specification of US2004/46497A, and the like. Hereinafter, for simplification, the organic layer and the organic region will be referred to as “the organic layer” and the inorganic layer and the inorganic region will be referred to as “the inorganic layer”.

The number of layers constituting the barrier laminate is not particularly limited; however, specifically, the number of layers is preferably in a range of 2 to 30 and more preferably in a range of 3 to 20. In addition, the barrier laminate may include functional layers other than the organic layers and the inorganic layers.

(Organic layer)

The organic layer is preferably an organic layer including an organic polymer as a main component. Here, the organic polymer as the main component means that the first component out of the components constituting the organic layer is an organic polymer and, generally, means that an organic polymer accounts for 80% by mass or more of the components constituting the organic layer.

Examples of the organic polymer include thermoplastic resins such as polyesters, acrylic resins, methacrylic resins, methacrylic acid-maleic acid copolymers, polystyrenes, transparent fluorine resins, polyimides, polyimide fluorides, polyamides, polyamide-imides, polyether-imides, cellulose acylates, polyurethanes, polyether ether ketones, polycarbonates, alicyclic polyolefins, polyacrylates, polyether sulfones, polysulfones, fluorene ring-denatured polycarbonates, alicyclic denatured polycarbonates, fluorene ring-denatured polyesters, and acryloyl compounds, organic silicon polymers such as polysiloxanes, and the like. The organic layer may be made of a single material or a mixture or may have a laminate structure including sub-layers. In this case, the respective sub-layers may have the same compositions or different compositions. In addition, as described above, the respective sub-layers may have unclear interfaces with the inorganic layers as disclosed by the specification of US2004/46497A and compositions that continuously change in the film thickness direction.

The organic layer is preferably formed of a polymerizable composition including a polymerizable compound and more preferably obtained by curing a polymerizable composition including a polymerizable compound.

(Polymerizable Compound Not Having Condensed Polycyclic Hydrocarbon Structure)

The barrier laminate of the present invention includes organic layers formed of a polymerizable composition that includes a polymerizable compound having a condensed polycyclic hydrocarbon structure described below.

The barrier laminate may include organic layers formed of a polymerizable composition that does not include a polymerizable compound having the condensed polycyclic hydrocarbon structure described below and, in this case, a polymerizable compound (another polymerizable compound) not having the condensed polycyclic hydrocarbon structure is used.

The polymerizable compound is preferably a radical polymerizable compound and/or a cationic polymerizable compound having an ether group as a functional group and more preferably a compound having an ethylenic unsaturated bond at the terminal or the side chain and/or a compound having epoxy or oxetane at the terminal or the side chain. Among these, the compound having an ethylenic unsaturated bond at the terminal or the side chain is preferred. Examples of the compound having an ethylenic unsaturated bond at the terminal or the side chain include (meth)acrylate-based compounds, acrylamide-based compounds, styrene-based compounds, anhydrous maleic acid, and the like. A (meth)acrylate-based compound and/or a styrene-based compound is preferred and a (meth)acrylate-based compound is more preferred.

As the (meth)acrylate-based compound, (meth)acrylates, urethane (meth)acrylates or polyester (meth)acrylates, epoxy (meth)acrylates, and the like are preferred.

As the styrene-based compound, styrene, α-methylstyrene, 4-methylstyrene, divinylbenzene, 4-hydroxystyrene, 4-carboxystyrene, and the like are preferred.

Hereinafter, specific examples of the (meth)acrylate-based compound that is preferably used in the present invention will be described, but the present invention is not limited thereto.

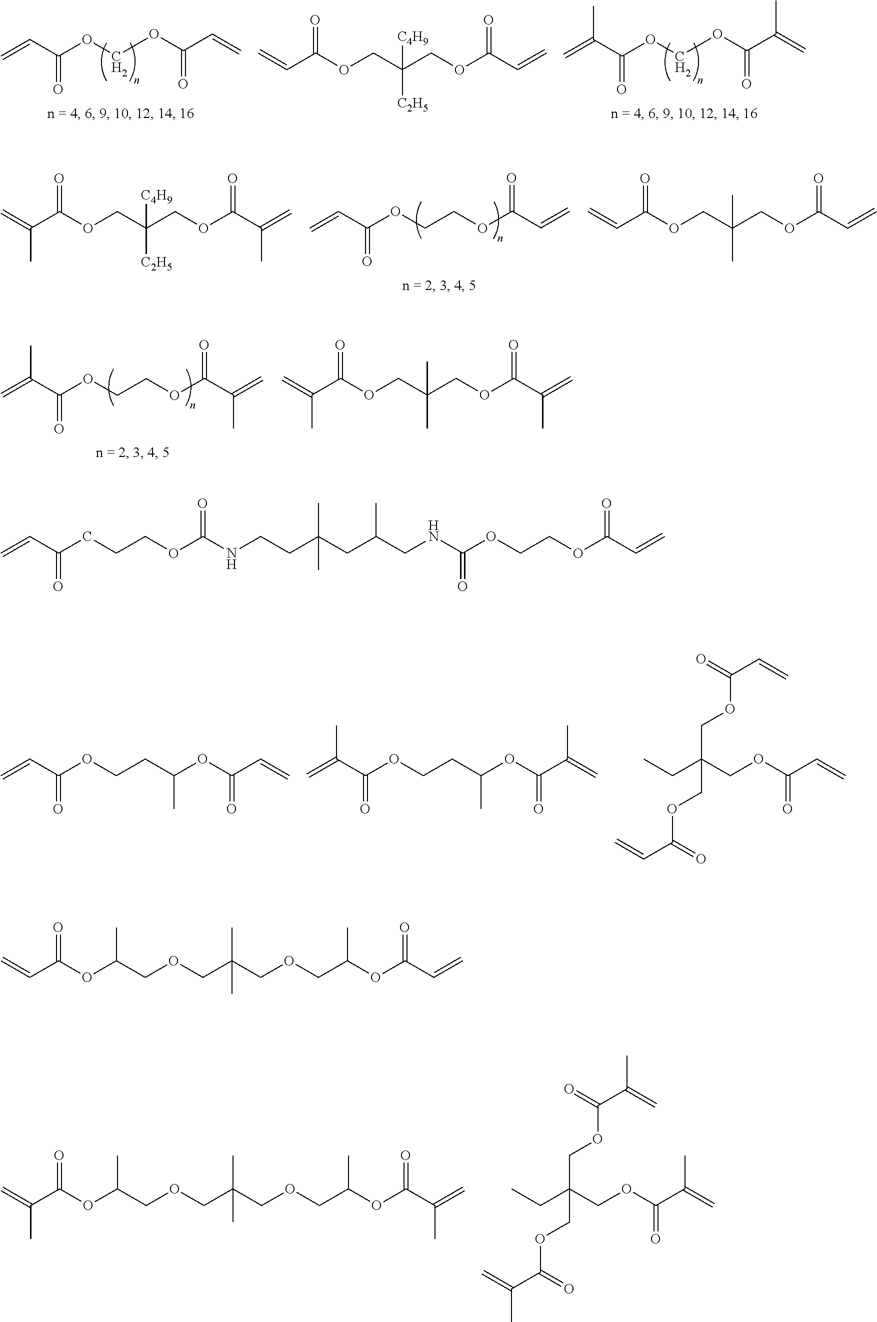

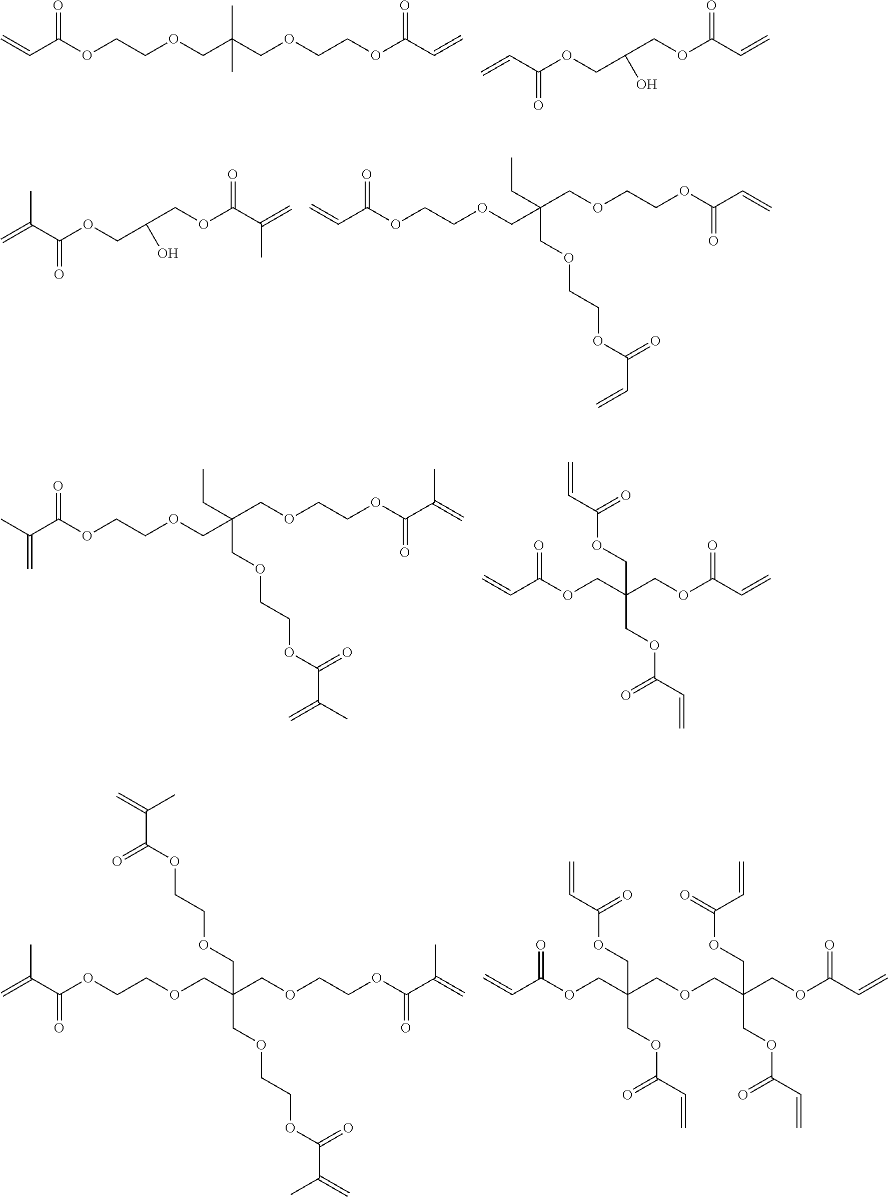

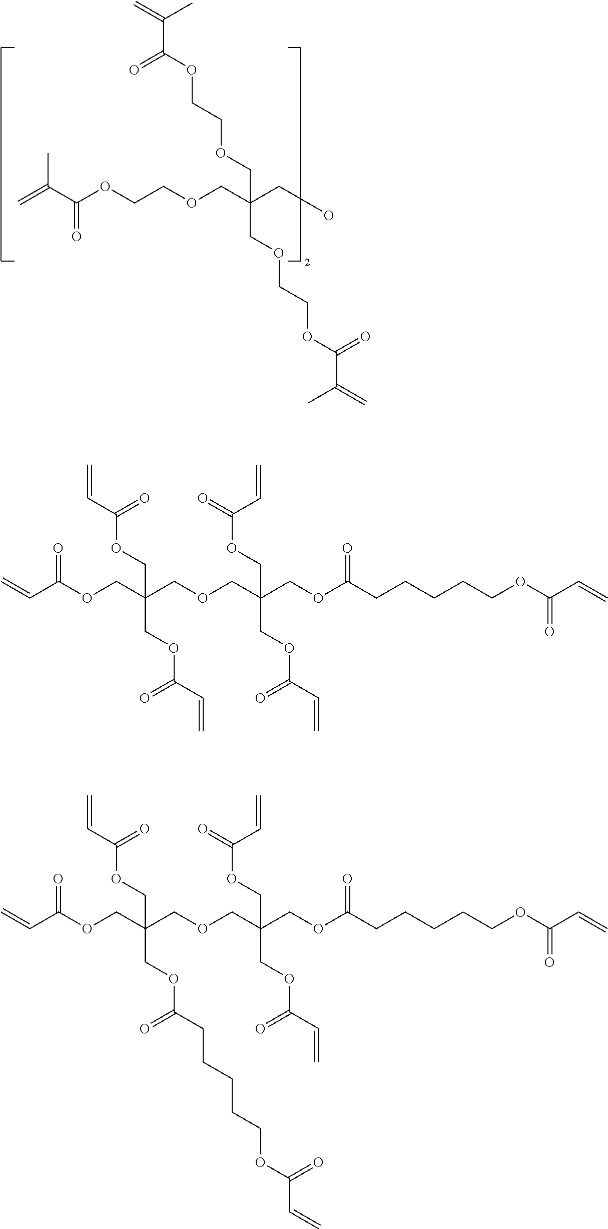

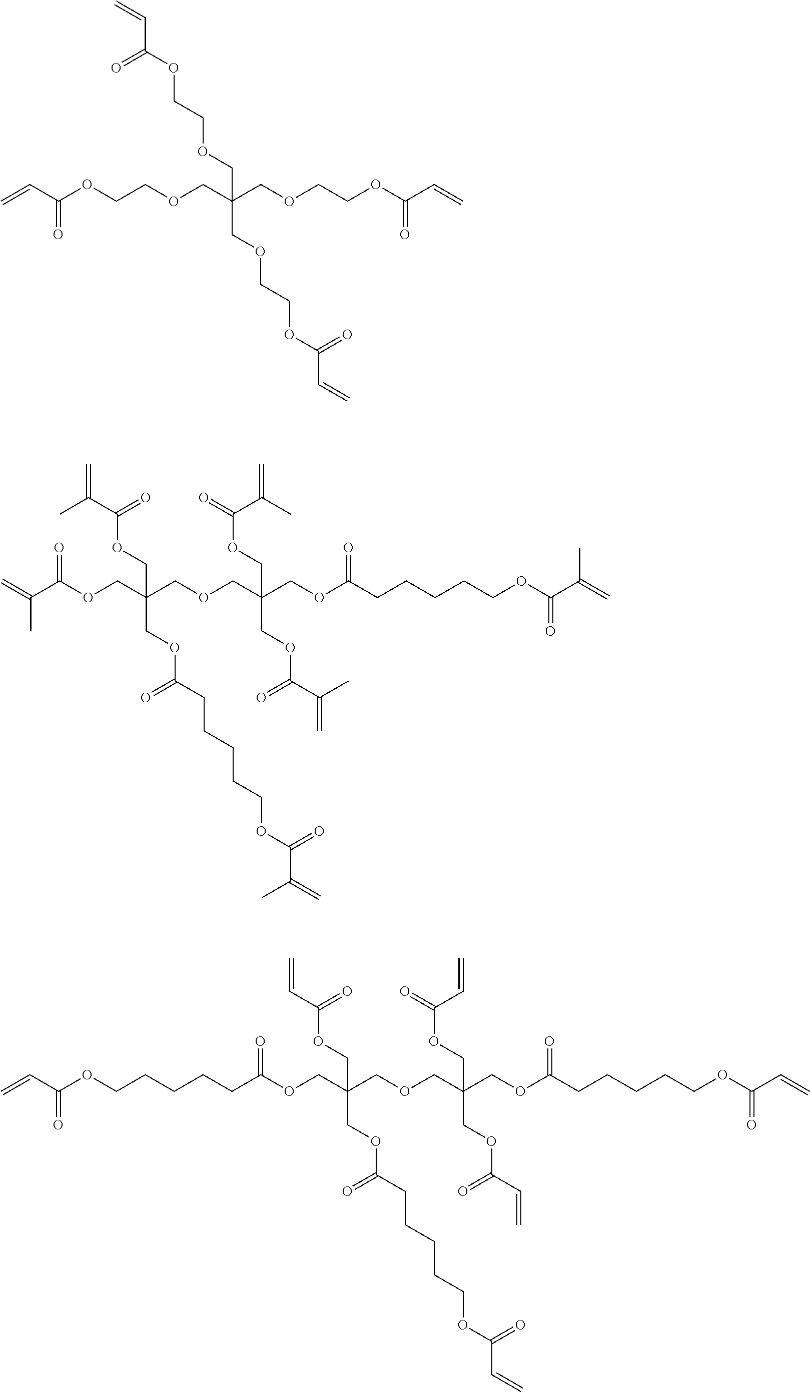

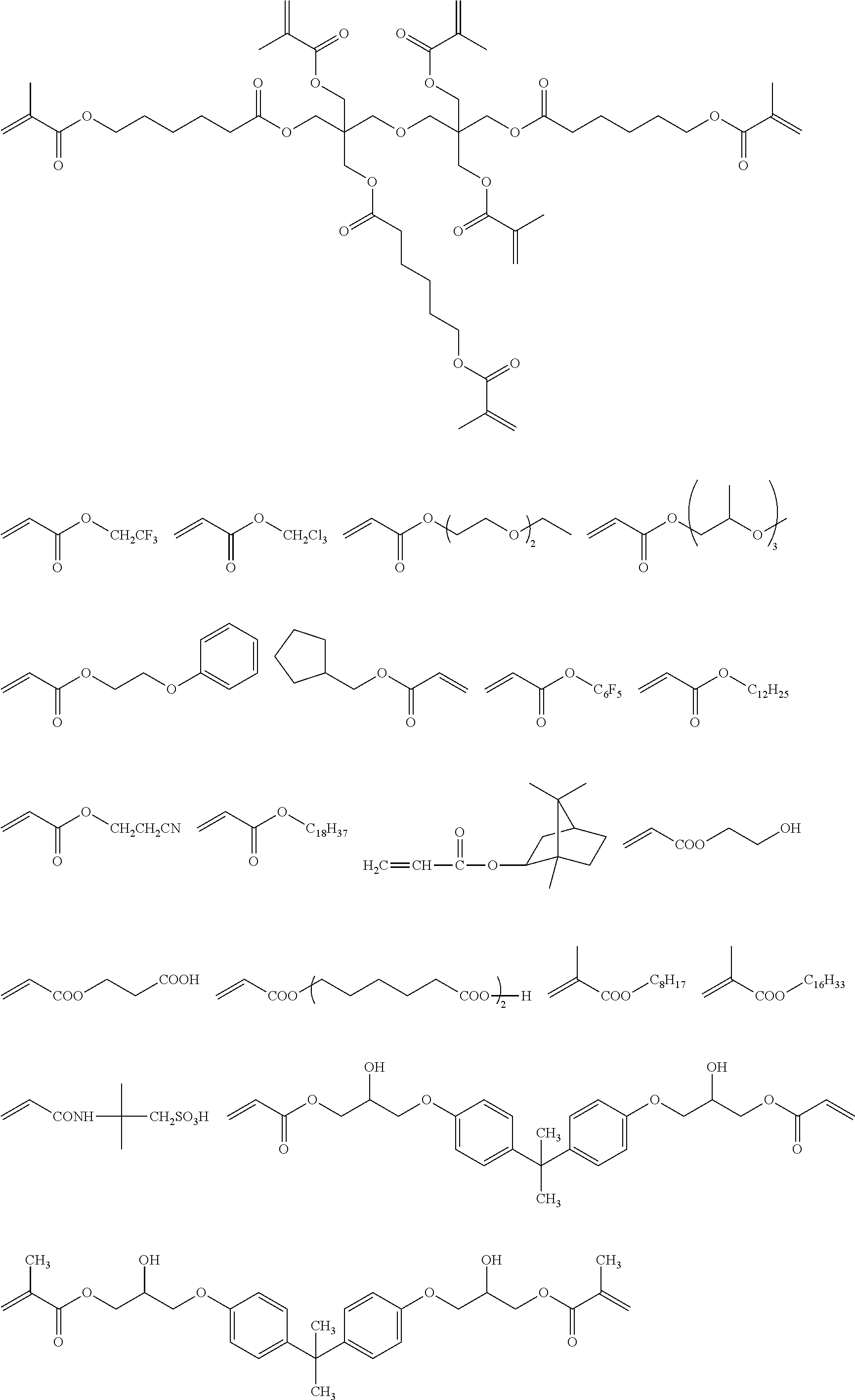

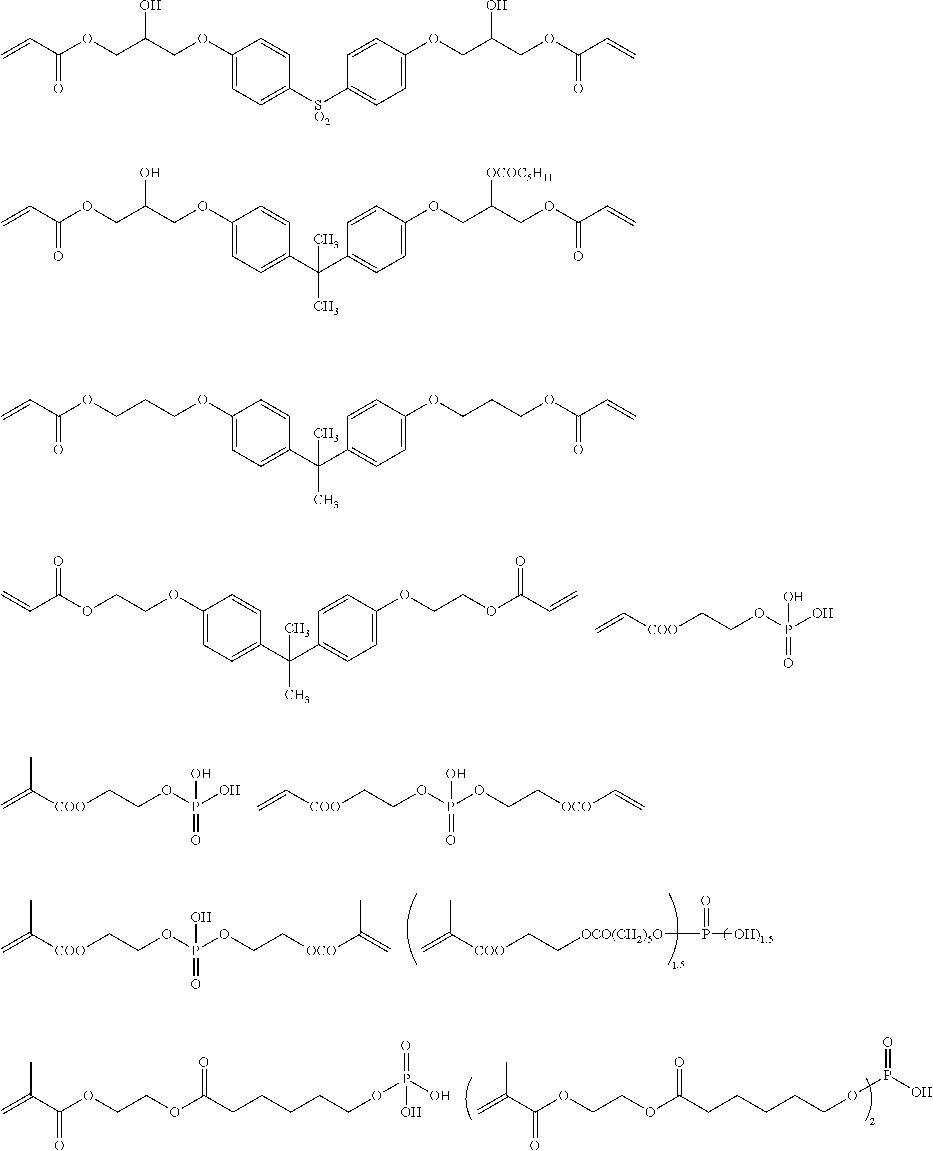

Furthermore, a compound represented by General Formula (10) described below can also be preferably used.

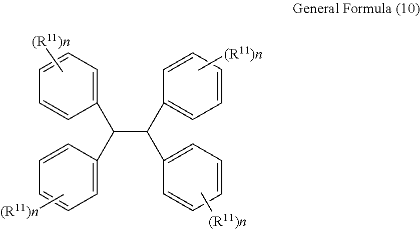

In General Formula (10), R¹¹'s represent substituents and may be identical to or different from each other. n's represent integers of 0 to 5 and may be identical to or different from each other. Here, at least one R¹¹ includes a polymerizable group.

Examples of the substituent of R¹¹ include groups obtained by combining one or more of —CR¹²₂— (R¹² represents a hydrogen atom or a substituent), —CO—, —O—, a phenylene group, —S—, —C═C—, —NR¹³— (R¹³ represents a hydrogen atom or a substituent), and —CR¹⁴═CR¹⁵— (each of R¹⁴ and R¹⁵ represents a hydrogen atom or a substituent) and a polymerizable group and groups obtained by combining one or more of —CR¹²₂— represents a hydrogen atom or a substituent), —CO—, —O—, and a phenylene group and a polymerizable group are preferred.

R¹² is a hydrogen atom or a substituent and is preferably a hydrogen atom or a hydroxyl group.

At least one of the R¹¹'s preferably has a hydroxyl group. When R¹¹ has a hydroxyl group, the curing rate of the organic layer improves.

The molecular weight of at least one of the R¹¹'s is preferably in a range of 10 to 250 and more preferably in a range of 70 to 150.

Regarding the position to which R¹¹ is bonded, R¹¹ is preferably bonded to at least the para position.

n's represent integers of 0 to 5 and are preferably integers of 0 to 2 and more preferably integers of 0 or 1 Still more preferably, all n's are 1.

In the compound represented by General Formula (10), at least two R¹¹'s preferably have the same structure. Furthermore, it is more preferable that the ns are all 1, two out of the four R¹¹'s have the same structure, and the remaining two R¹¹'s have the same structure and it is still more preferable that the ns are all 1 and the four R¹¹'s have the same structure. The polymerizable group in General Formula (10) is preferably a (meth)acryloyl group or an epoxy group and more preferably a (meth)acryloyl group. The number of the polymerizable groups in General Formula (10) is preferably 2 or more and more preferably 3 or more. In addition, the upper limit thereof is not particularly specified, but is preferably 8 or less and more preferably 6 or less.

The molecular weight of the compound represented by General Formula (10) is preferably in a range of 600 to 1400 and more preferably in a range of 800 to 1200.

Hereinafter, specific examples of the compound represented by General Formula (10) will be described, but the present invention is not limited thereto. In addition, in the compounds described below, cases in which the four n's in General Formula (10) are all 1 will be exemplified, but cases in which one, two, or three of the four n's in General Formula (10) are 0 (for example, difunctional or trifunctional compounds and the like) or cases in which one, two, or three of the four n's in General Formula (10) are 2 or more (compounds in which two or more R¹¹'s are bonded to a single ring, for example, pentafunctional or hexafunctional compounds and the like) are also be exemplified as preferred compounds.

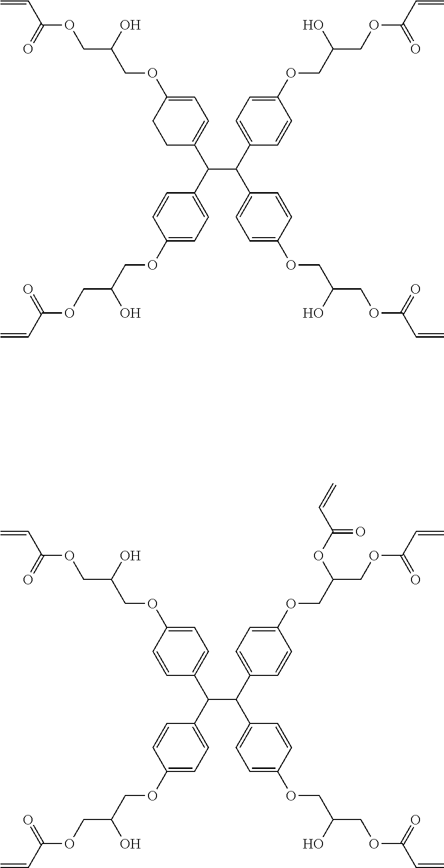

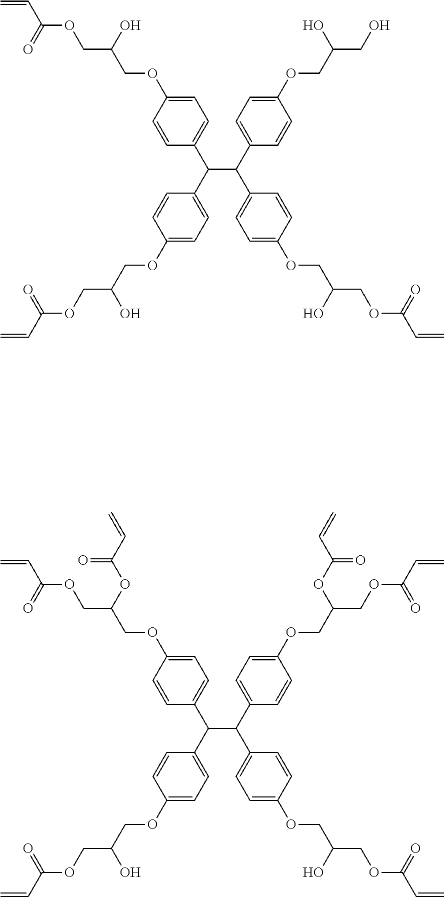

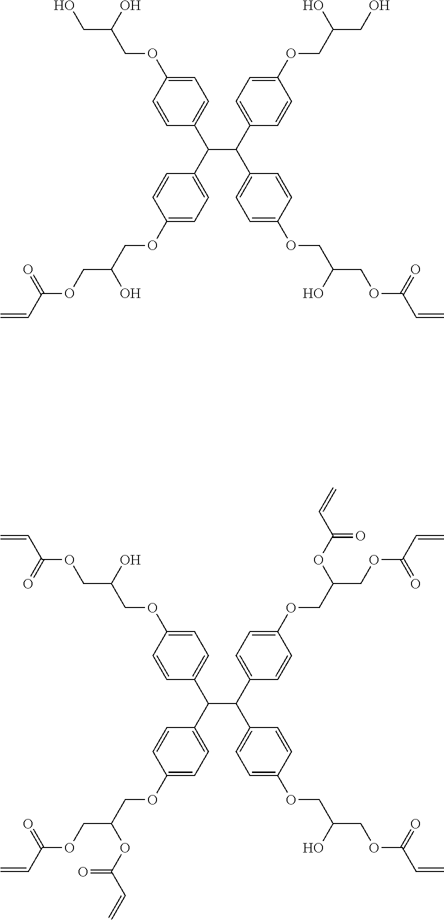

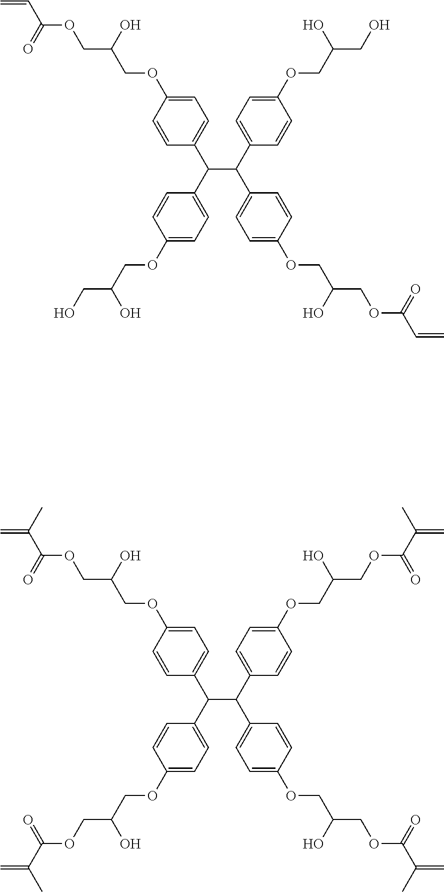

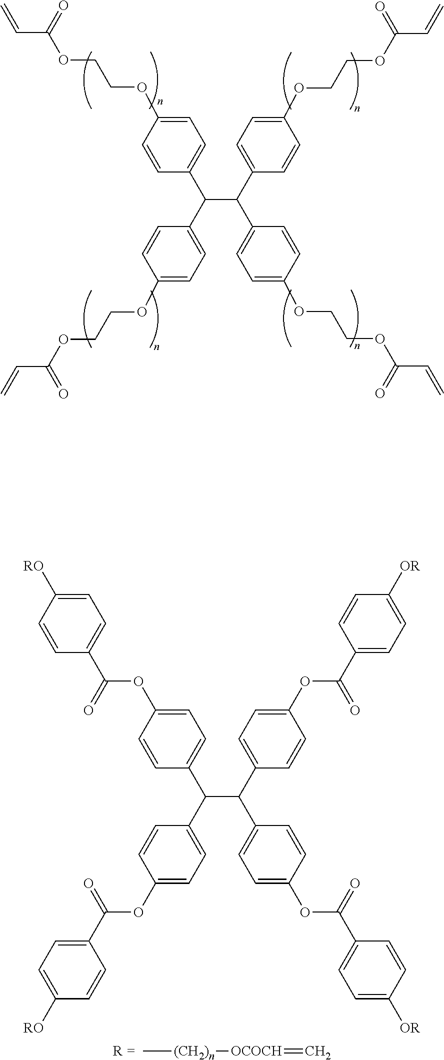

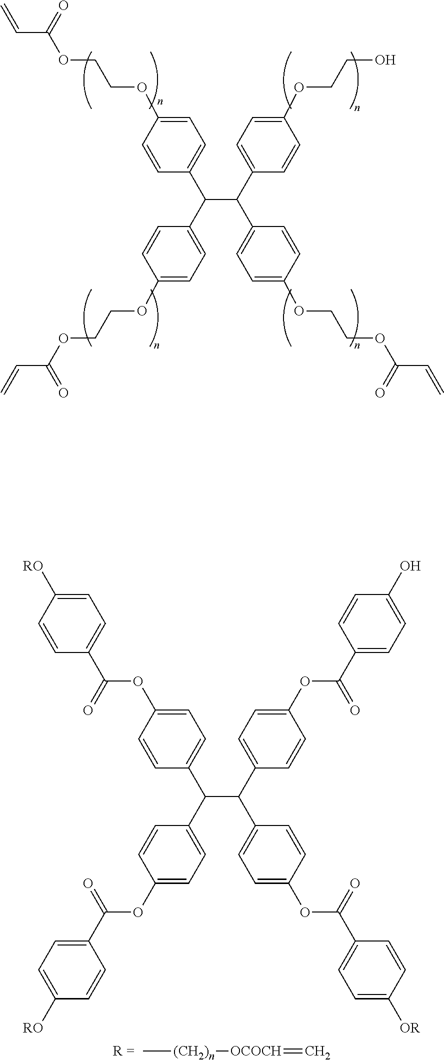

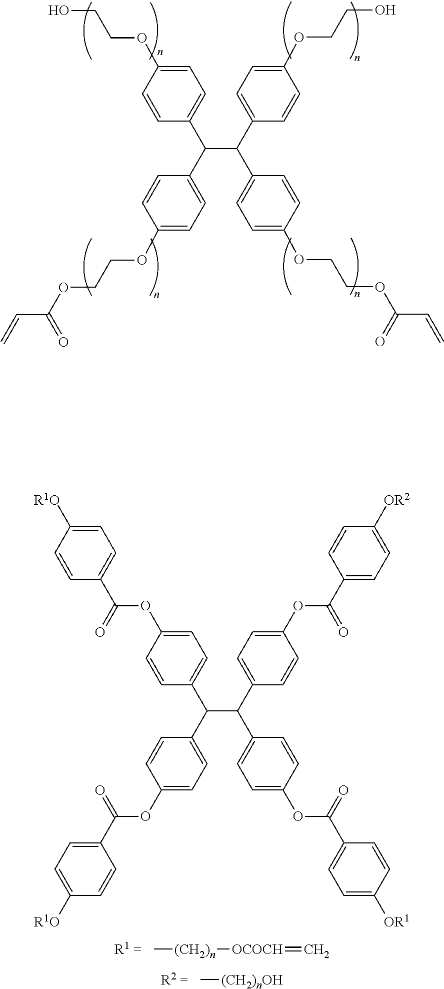

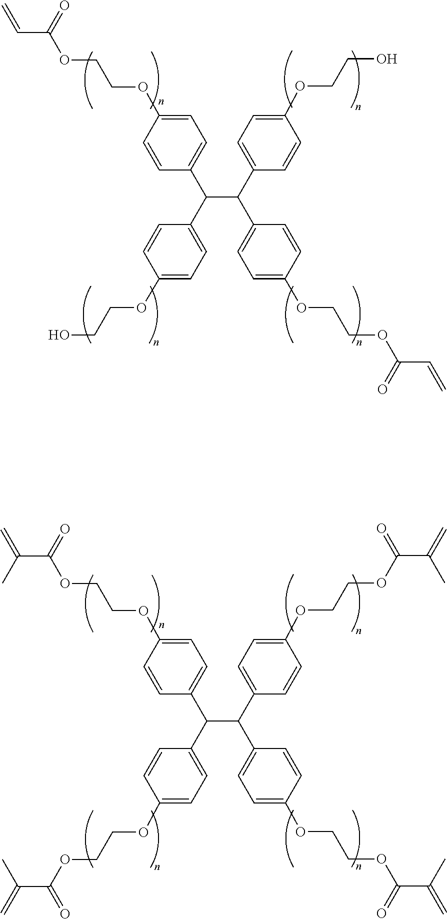

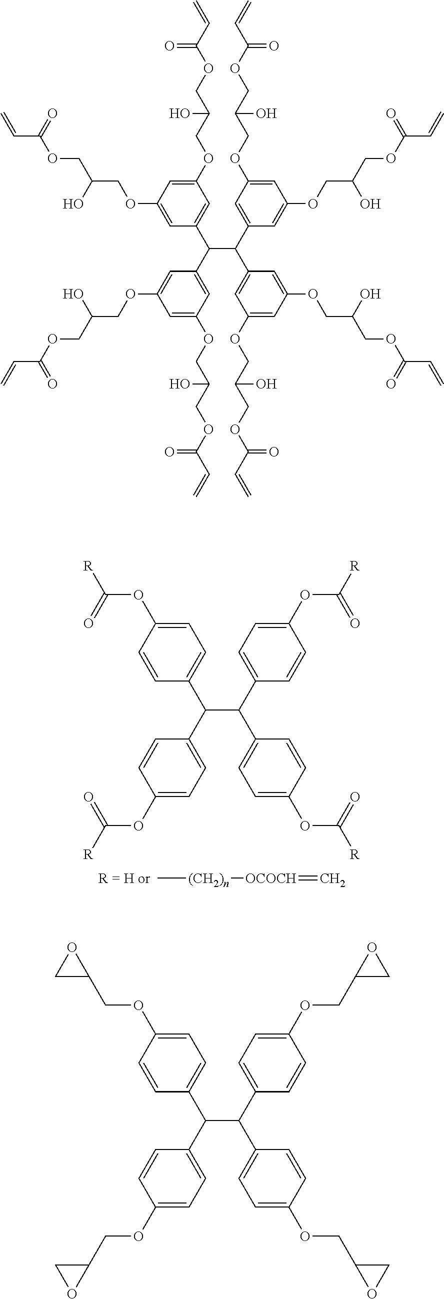

The compound represented by General Formula (10) can be procured from commercially available products. In addition, the compound can also be synthesized using a well-known method. For example, epoxy acrylate can be obtained by reacting an epoxy compound and acrylic acid. Generally, this compound also generates a difunctional compound, a trifunctional compound, a pentafunctional compound, an isomer thereof, or the like during the reaction. In a case in which it is necessary to separate out the above-descried isomer, the isomer can be separated out through column chromatography; however, in the present invention, the isomer can also be used as a mixture,

(Polymerizable Compound Having Condensed Polycyclic Hydrocarbon Structure)

The barrier laminate includes at least one organic layer that is a layer formed of a polymerizable composition including a polymerizable compound and the polymerizable compound has a condensed polycyclic hydrocarbon structure. The polymerizable compound may only include a polymerizable compound having the condensed polycyclic hydrocarbon structure or may also include another polymerizable compound at the same time. The organic layer formed of a polymerizable composition including the polymerizable compound is preferably adjacent to a support and, particularly, is in direct contact with the support in the gas barrier film.

The condensed polycyclic hydrocarbon structure refers to a structure in which multiple cycloalkanes are condensed or a structure in which one or more cycloalkanes and one or more cycloalkenes are condensed with each other and also refers to a crosslinked structure. The number of carbon atoms in the condensed polycyclic hydrocarbon structure is generally in a range of approximately 8 to 50, preferably in a range of 8 to 25, more preferably in a range of 8 to 20, and still more preferably in a range of 10 to 15. Examples of the condensed polycyclic hydrocarbon structure will be described below, but the condensed polycyclic hydrocarbon structure is not limited the following structures.

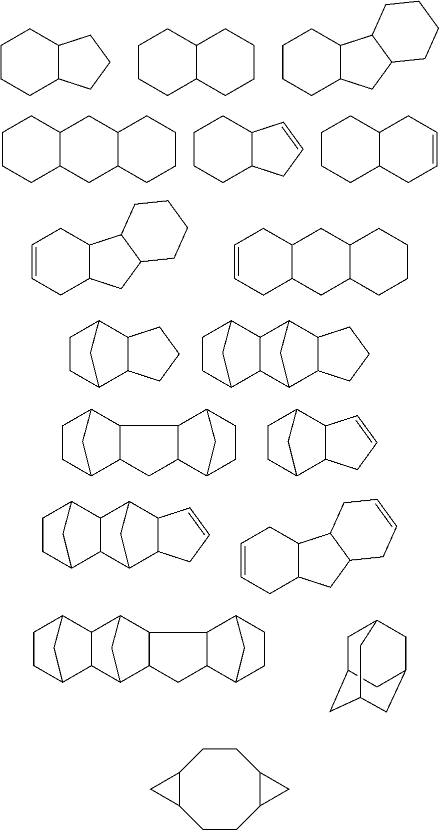

As the condensed polycyclic hydrocarbon structure, the following structures are more preferred.

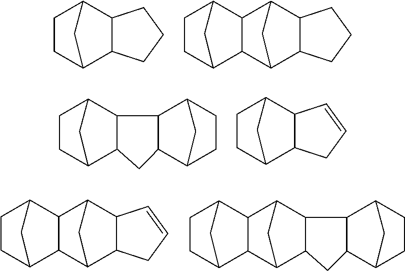

Among these, the following structures are particularly preferred.

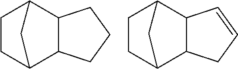

The polymerizable compound having the condensed polycyclic hydrocarbon structure has a polymerizable group in addition to the condensed polycyclic hydrocarbon structure. Specifically, the polymerizable compound having the condensed polycyclic hydrocarbon structure needs to have a structure in which a substituent having a polymerizable group is bonded to the condensed polycyclic hydrocarbon structure.

Examples of the polymerizable group include polymerizable groups in the above-described radical polymerizable compounds and/or the above-described cationic polymerizable compounds having an ether group as a functional group. The polymerizable group may be bonded to the condensed polycyclic hydrocarbon structure directly or through a divalent linking group.

The number of the substituents having a polymerizable group bonded to the condensed polycyclic hydrocarbon structure may be one or more. There is no particular limitation regarding the bonding position of the substituent having a polymerizable group, but a structure in which the substituents are bonded to carbon atoms that constitute only a single ring is preferred. In a case in which two or more substituents are bonded, all the substituents are preferably bonded to carbon atoms that constitute only a single ring and are preferably bonded to mutually different carbon atoms that constitute the same ring.

The polymerizable compound having the condensed polycyclic hydrocarbon structure preferably has an Ohnish parameter from 3.0 to 5.0. The Ohnish parameter refers to the density of carbon per polymerizable unit volume and, specifically, is a parameter obtained using the following expression on the basis of the chemical formula of the polymerizable compound.

Expression: (the total number of C, H, and O atoms)/(the number of C atoms−the number of O atoms)

The polymerizable compound having the condensed polycyclic hydrocarbon structure is, for example, a compound represented by General Formula (I) described below.

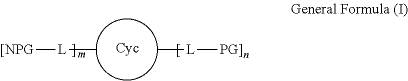

In the formula, Cyc represents a condensed polycyclic hydrocarbon residue, each of L's independently represents a single bond or a divalent linking group, PG represents a polymerizable group, in a case in which multiple PGs are present, each of the PGs independently represents a polymerizable group, NPG represents a non-polymerizable group, in a case in which multiple NPGs are present, each of the NPGs independently represents a non-polymerizable group, n is an integer selected from 1 to 4, and m is an integer selected from 0 to 4.

The number of carbon atoms in the condensed polycyclic hydrocarbon residue is generally in a range of approximately 8 to 50, preferably in a range of 8 to 25, more preferably in a range of 8 to 20, and still more preferably in a range of 10 to 15. Examples of the condensed polycyclic hydrocarbon-structured residue of General Formula (1) include residues obtained by removing (m+n) hydrogen atoms from the condensed polycyclic hydrocarbon structure in the example of the condensed polycyclic hydrocarbon structure.

The (m+n) L's may be identical to or different from each other and each of the L's independently represents a bond or a divalent linking group.

The divalent linking group is not particularly limited and examples thereof include an alkylene group (for example, an ethylene group, a 1,2-propylene group, a 2,2-propylene group (also referred to as a 2,2-propylidene group or a 1,1-dimethylmethylene group), a 1,3-propylene group, a 2,2-dimethyl-1,3-propylene group, a 2-butyl-2-ethyl-1,3-propylene group, a 1,6-hexylene group, a 1,9-nonylene group, a 1,12-dodecylene group, a 1,16-hexadecylene group, or the like), an arylene group (for example, a phenylene group or a naphthylene group)an ether group, an imino group, a carbonyl group, a sulfonyl group, and divalent residues obtained by bonding a plurality of the above-described divalent groups in series (for example, an oxyethylene group, an oxypropylene group, a 2,2-propylene phenylene group, and the like). Examples of the preferred divalent linking group include an alkylene group and groups obtained by bonding an alkylene group and an ether group (oxyalkylene groups). At this time, any of the alkylene group and the ether group may be bonded to Cyc. Examples of a more preferred divalent linking group include a methylene group, an ethylene group, a 1,3-propylene group, and an oxyethylene group.

The n PGs may be identical to or different from each other and each of the PGs independently represents a polymerizable group.

Examples of the polymerizable group include the polymerizable groups in the above-described radical polymerizable compounds and/or the above-described cationic polymerizable compounds having an ether group as a functional group and specific examples thereof include a (meth)acryloyl group, a vinyl group, an epoxy group, an oxetanyl group, and a vinyl ether group. Particularly preferred examples thereof include (meth)acryloyl groups.

The m NPGs may be identical to or different from each other and each of the PGs independently represents a non-polymerizable group.

Examples of the non-polymerizable group include an alkyl group (for example, a methyl group, an ethyl group, an isopropyl group, a tert-butyl group, an n-octyl group, an n-decyl group, an n-hexadecyl group, a cyclopropyl group, a cyclopentyl group, a cylcohexyl group, or the like), an alkenyl group (for example, a vinyl group, an allyl group, a 2-butenyl group, a 3-pentenyl group, or the like), an aryl group (for example, a phenyl group, a p-methylphenyl group, a naphthyl group, an anthryl group, a phenanthryl group, a pyrenyl group, or the like), a halogen atom (for example, fluorine, chlorine, bromine, or iodine), a hydroxyl group, an acyl group (for example, an acetyl group, a benzoyl group, a formyl group, a pivaloyl group, or the like), an acyloxy group (for example, an acetoxy group, an acryloyloxy group, a methacryloyloxy group, or the like), an alkoxycarbonyl group (for example, a methoxycarbonyl group, an ethoxycarbonyl group, or the like), an aryloxycarbonyl group (for example, a phenyloxycarbonyl group or the like), a sulfonyl group (for example, a methanesulfonyl group, a benzenesulfonyl group, or the like), a sulfonyl group (a methanesulfinyl group, a benzenesulfinyl group, or the like), a heterocyclic group (which preferably has 1 to 12 carbon atoms, includes a nitrogen atom, an oxygen atom, a sulfur atom, or the like as a hetero atom, and may be an aliphatic heterocyclic group or a heteraryl group; examples thereof include an imidazolyl group, a pyridyl group, a quinolyl group, a furyl group, a thienyl group, a piperidyl group, a morpholino group, a benzoxazolyl group, a benzoimidazolyl group, a benzothiazolyl group, a carbazolyl group, an azepinyl group, or the like), and the like.

The n is preferably 1 or 2 and the m is preferably 0 or 1.

Examples of the polymerizable compound having the condensed polycyclic hydrocarbon structure will be described below.

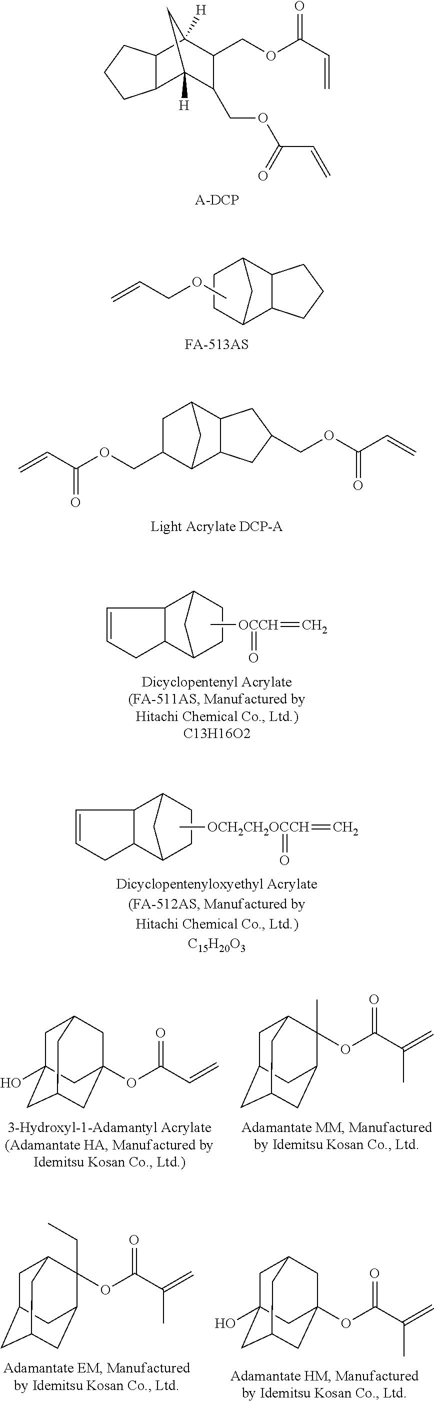

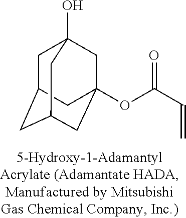 [SMILES: C=CC(=O)OC12CC3CC(CC(O)(C3)C1)C2]

The content of the polymerizable compound with respect to the solid content of the polymerizable composition is preferably 80% by mass or more and more preferably 90% by mass or more.

The content of the polymerizable compound having the condensed polycyclic hydrocarbon structure may be 50% by mass or more, 60% by mass or more, 70% by mass or more, 80% by mass or more, or 90% by mass or more and is also preferably 100% by mass with respect to the total amount of the polymerizable compound in the polymerizable composition. Polymerizable compounds other than the polymerizable compound having the condensed polycyclic hydrocarbon structure preferably have the same polymerizable group as the polymerizable compound having the condensed polycyclic hydrocarbon structure. Examples of the other polymerizable compounds in the organic layer including the polymerizable compound having the condensed polycyclic hydrocarbon structure and the other polymerizable compounds include polymerizable compounds not having the above-described condensed polycyclic hydrocarbon structure.

(Silane Coupling Agent)

In order to impart the humid and heat durability of the barrier laminate, a silane coupling agent may be added to the polymerizable composition. In a case in which the organic layer is formed directly on the inorganic layer including a silicon oxide, a silicon nitride, a silicon carbide, or a mixture thereof a silane coupling agent is preferably added in order to strengthening adhesiveness between the organic layer and the inorganic layer.

The silane coupling agent needs to be a substance derived from an organic silicon compound having both a hydrolytic group that reacts with an inorganic substance and an organic functional group that reacts with an organic substance in a single molecule. Examples of the hydrolytic group that reacts with an inorganic substance include alkoxy groups such as a methoxy group and an ethoxy group, acetoxy groups, chloro groups, and the like. In addition, examples of the organic functional group that reacts with an organic substance include a (meth)acryloyl group, an epoxy group, a vinyl group, an isocyanate group, an amino group, and a mercapto group, however, in the present invention, a silane coupling agent having a (meth)acryloyl group is preferably used.

The organic silicon compound may have an alkyl group or a phenyl group that reacts with neither an inorganic substance nor an organic substance. In addition, it is also possible to mix the organic silicon compound with a compound such as a silicon compound not having an organic functional group, for example, an alkoxysilane only having a hydrolytic group. The silane coupling agent may be used singly or a mixture of two or more silane coupling agents may be used.

Examples of the silane coupling agent include 3-acryloxypropyl trimethoxysilane, 3-methacryloxypropyl methyl dimethoxysilane, 3-methacryloxypropyl triethoxysilane, 2-(3,4-epoxycyclohexyl) ethyl trimethoxysilane, 3-isocyanatepropyl triethoxysilane, 3 -isocyanatepropyl trimethoxysilane, N-(2-aminoethyl)-3-aminopropyl methyl dimethoxysilane, N-(2-aminoethyl)-3-aminopropyl trimethoxysilane, 3-aminopropyl trimethoxysilane, 3-mercaptopropyl methyl dimethoxysilane, and the like.

The amount of the silane coupling agent may be in a range of 1% by mass to 30% by mass and preferably in a range of 5% by mass to 20% by mass in the solid content (the remaining components after volatile components volatilize) of the polymerizable compound.

(Polymerization Initiator)

The polymerizable composition generally includes a polymerization initiator. In a case in which a polymerization initiator is used, the content thereof is preferably 0.1% by mole or more and more preferably in a range of 0.5% by mole to 2% by mole of the total amount of compounds that participate in polymerization. When the above-described composition is produced, it is possible to appropriately control the polymerization reaction that passes through an active component generation reaction. Examples of the photopolymerization initiator include IRGACURE series (for example, IRGACURE 651, IRGACURE 754, IRGACURE 184, IRGACURE 2959, IRGACURE 907, IRGACURE 369, IRGACURE 379, IRGACURE 819, and the like), DAROCURE series (for example, DAROCURE TPO, DAROCURE 1173, and the like), and QUANTACURE PDO, all of which are made to be commercially available by BASF Japan Ltd., and ESACURE series (for example, ESACURE TZM, ESACURE TZT, ESACURE KT046, and the like) and ESACURE KIP series, both of which are made to be commercially available by Lamberti S.p., and the like.

(Solvent)

The polymerizable composition generally includes a solvent. Examples of the solvent include ketones and ester-based solvents and 2-butanone, propylene glycol monoethyl ether acetate, and cyclohexanone are preferred. The content of the solvent is preferably in a range of 60% by mass to 97% by mass and more preferably in a range of 70% by mass to 95% by mass of the polymerizable composition.

(Method for Forming Organic Layer)

Examples of a method for forming the organic layer from the polymerizable composition include a method in which the polymerizable composition is applied onto a plastic film or onto a functional layer or an inorganic layer on the plastic film and then is cured using light (for example, an ultraviolet ray), an electronic beam, or a heat ray.

As the application method, it is possible to employ a dip coating method, an air knife coating method, a curtain coating method, a roller coating method, a wire bar coating method, a gravure coating method, a slide coating method, a spin coating method, or an extrusion coating method in which a hopper is used, which is described in the specification of U.S. Pat. No. 268,294B.

In addition, the organic layer may be formed using a vacuum film-forming method such as a flash deposition method.

The polymerizable composition is preferably cured using light. The light being radiated is generally an ultraviolet ray from a high-pressure mercury lamp or a low-pressure mercury lamp. The radiation energy is preferably 0.1 J/cm² or more and more preferably 0.5 J/cm² or more. In a case in which a (meth)acrylate-based compound is used as the polymerizable compound, polymerization is hindered due to oxygen in the air and thus the concentration of oxygen or the partial pressure of oxygen is preferably set to be low during polymerization. In a case in which the partial pressure of oxygen during polymerization is decreased using a nitrogen substitution method, the concentration of oxygen is preferably 2% or lower and more preferably 0.5% or lower. In a case in which the partial pressure of oxygen during polymerization is decreased using a depressurization method, the total pressure is preferably 1000 Pa or lower and more preferably 100 Pa or lower. In addition, it is particularly preferable to carry out ultraviolet polarization by radiating energy of 0.5 J/cm² or more under a depressurization condition of 100 Pa or lower.

The organic layer is preferably flat and has high film hardness. The flatness of the organic layer is preferably less than 1 nm and more preferably less than 0.5 nm in terms of the 1 μm×1 μm average roughness (Ra value). The polymerization ratio of a monomer is preferably 85% or more, more preferably 88% or more, still more preferably 90% or more, and particularly preferably 92% or more. The polymerization ratio mentioned herein refers to the ratio of reacted polymerizable groups to all the polymerizable groups (for example, an acryloyl group and a methacryloyl group) in a monomer mixture. The polymerization rate can be determined using an infrared absorption method.

There is no particular limitation regarding the film thickness of the organic layer. However, when the organic layer is too thin, it becomes difficult to obtain the uniformity of the film thickness and, when the organic layer is too thick, an external force causes cracks and thus the barrier properties degrade. From the above-described viewpoint, the film thickness of the organic layer is preferably in a range of 50 nm to 5000 nm, more preferably in a range of 200 nm to 4000 nm, and still more preferably in a range of 300 nm to 3000 nm.

The surface of the organic layer needs to be clear of foreign substances such as particles and projections. Therefore, the organic layer is preferably formed in a clean room. The clean room standard is preferably class 10000 or less and more preferably class 1000 or less.

(Inorganic Layer)

The inorganic layer is a layer included in the barrier laminate and is generally a thin film layer made of a metallic compound. As the method for forming the inorganic layer, any method can be used as long as the target thin film can be formed. Examples thereof include physical vapor deposition (PVD) methods such as a deposition method, a sputtering method, and an ion plating method, a variety of chemical vapor deposition (CVD) methods, and liquid-phase growth methods such as plating and a sol-gel method and a plasma CVD method is preferred. The components included in the inorganic layer are not particularly limited as long as the above-described performance is satisfied and examples thereof include a metallic oxide, a metallic nitride, a metallic carbide, a metallic oxynitride, and a metallic oxycarbide. An oxide, a nitride, a carbide, an oxynitride, an oxycarbide, and the like which include one or more metals selected from Si, Al, In, Sn, Zn, Ti, Cu, Ce, and Ta can be preferably used. Among these, an oxide, a nitride, and an oxynitride including metals selected from Si, Al, In, Sn, Zn, and Ti are preferred, an oxide or a nitride of Si or Al is more preferred, and silicon nitride (Si nitride) is particularly preferred. These components may contain other elements as auxiliary components. For example, the silicon nitride may contain hydrogen and thus turn into hydrogenated silicon nitride and may further contain oxygen and thus turn into hydrogenated silicon oxynitride.

The flatness of the inorganic layer formed by the present invention is preferably less than 1 nm and more preferably 0.5 nm or less in terms of the 1 μm×1 μm average roughness (Ra value). Therefore, the inorganic layer is preferably formed in a clean room. The clean room standard is preferably class 10000 or less and more preferably class 1000 or less.

The film thickness of the inorganic layer per layer is generally in a range of 5 nm to 500 nm and preferably in a range of 10 nm to 200 nm. The film thickness of the inorganic layer may be greater than 20 nm and, in some cases, is 30 nm or more or 40 nm or more. In addition, the film thickness of the inorganic layer may be 100 nm or less, 50 nm or less, or 35 nm or less.

The inorganic layer may have a laminate structure including multiple sub-layers. In this case, the respective sub-layers may have the same compositions or different compositions. In addition, as described above, the inorganic layer may be a layer which has an unclear interface with the organic layer as described in US2004/46497A and has a composition that continuously changes in the film thickness direction.

(Method for Forming Inorganic Layer)

The inorganic layer can be formed using a vacuum film-forming method such as a sputtering method, a vacuum deposition method, an ion-plating method, or a plasma CVD method.

(Lamination of Organic Layers and Inorganic Layers)

The organic layers and the inorganic layers can be laminated together by sequentially repeating the formation of the organic layers and the inorganic layers in accordance with a desired layer constitution. The lamination sequence may be either a lamination sequence of the organic layer/the inorganic layer from the support side or a lamination sequence of the inorganic layer/the organic layer from the support side, but the lamination sequence of the organic layer/the inorganic layer from the support side is preferred.

In a case in which at least two organic layers and at least two inorganic layers are alternately laminated together, it is possible to exhibit high barrier properties. The alternate lamination sequence from the support side may be, for example, a sequence of the organic layer/the inorganic layer/the organic layer/the inorganic layer, a sequence of the organic layer/the inorganic layer/the organic layer/the inorganic layer/the organic layer/the inorganic layer, a sequence of the inorganic layer/the organic layer/the inorganic layer/the organic layer, a sequence of the inorganic layer/the organic layer/the inorganic layer/the organic layer/the inorganic layer/the organic layer, or the like.

In a case in which the barrier laminate includes two or more organic layers, all of the organic layers may be formed of a polymerizable composition including a polymerizable compound having the condensed polycyclic hydrocarbon structure or parts of the organic layers may be formed of a polymerizable composition including a polymerizable compound having the condensed polycyclic hydrocarbon structure. In the latter case, at least the organic layer closest to the support is preferably formed of a polymerizable composition including a polymerizable compound having the condensed polycyclic hydrocarbon structure. At this time, the organic layer closest to the support is more preferably adjacent to the support.

(Gas Barrier Film)

A gas barrier film needs to include a support and the barrier laminate. Preferably, the barrier laminate is directly provided on the surface of the support.

In the gas barrier film, the barrier laminate may be only provided on a single surface of the support or the barrier laminates may be provided on both surfaces of the support. In the gas barrier film, the lamination sequence from the support side may be either a lamination sequence of the inorganic layer and the organic layer or a lamination sequence of the organic layer and the inorganic layer, but is preferably a lamination sequence of the organic layer and the inorganic layer from the support side. It is preferable that the organic layer and the inorganic layer are sequentially laminated together from the support side and the support is adjacent to the organic layer. Here, the support being adjacent to the organic layer means that the support is in direct contact with the organic layer and specific examples thereof include a case in which the organic layer is directly provided on the surface of the support.

The gas barrier film may include constituent components other than the barrier laminate and the support (for example, functional layers such as an easy adhesion layer). The functional layers may be installed on the barrier laminate, between the barrier laminate and the support, or on a side not provided with the barrier laminate out of the surfaces of the support (the rear surface).

The gas barrier film may be transparent or opaque, but is preferably transparent. In addition, the gas barrier film of the present invention preferably has low birefringence. The low birefringence means that the retardation (Re) is 20 nm or less and the retardation is preferably 10 nm or less and more preferably 5 nm or less. In the present specification, the retardation (Re) refers to the front surface retardation unless particularly otherwise specified. In the present specification, the Re refers to a value measured for each of R, G, and B at a wavelength of 611±5 nm, 545±5 nm, or 435±5 nm respectively and refers to a value measured at a wavelength of 545±5 nm as long as there is no particular description regarding color. The gas barrier film of the present invention also preferably has birefringence suitable for the characteristics of a device in which the gas barrier film of the present invention is used. In addition, the gas barrier film is preferably an electrically-insulating film. Particularly, the respective constitution conditions included in the barrier film (for example, the inorganic layer, the organic layer, and the like) are preferably electrically-insulating conditions.

(Support)

The support in the gas barrier film is preferably a plastic film. As long as the plastic film is capable of holding the barrier laminate, there is no particular limitation regarding the material, the film thickness, and the like and the plastic film can be appropriately selected in accordance with the purpose of the gas barrier film being used. Depending on the type of an organic electronic device, there are cases in which a transparent plastic film or a film having high optical characteristics is preferred. Specific examples of the plastic film include thermoplastic resins such as a polyester resin, a methacrylic resin, a methacrylic acid-maleic acid copolymer, a polystyrene resin, a transparent fluorine resin, a polyimide, a polyimide fluoride resin, a polyamide resin, a polyamide-imide resin, a polyether-imide resin, a cellulose acylate resin, a polyurethane resin, a polyether ether ketone resin, a polycarbonate resin, an alicyclic polyolefin resin, a polyacrylate resin, a polyether sulfone resin, a polysulfone resin, a cycloolefin polymer, a cycloolefin copolymer, a fluorene ring-denatured polycarbonate resin, an alicyclic denatured polycarbonate resin, a fluorene ring-denatured polyester resin, and an acryloyl compound. The plastic film is preferably a polyester resin or a so-called optical film. The polyester resin is more preferably polyethylene terephthalate (PET) or polyethylene naphthalate (PEN) and the optical film is more preferably a cycloolefin polymer, a cycloolefin copolymer, or a polycarbonate resin.

The thickness of the support is not particularly limited and, for example, a support having a thickness in a range of 1 μm to 800 μm, 10 μm to 400 μm, 20 μm to 200 μm, or 50 μm to 100 μm may be used.

As the support, a support having low birefringence (a retardation (Re) of preferably 10 nm or less and more preferably 5 nm or less) is also preferably used.

The support is more preferably a film including a polymer having a cyclic olefin as a repeating unit structure (a cycloolefin polymer, a cycloolefin copolymer, or the like). The film is known for its low birefringence and, when used in combination with the barrier laminate of the present invention, it is possible to obtain a gas barrier film having high barrier properties. The high barrier properties are considered to be derived from high adhesiveness between the support and the barrier laminate, particularly, between the support and the organic layer in the barrier laminate. A polymer having a cyclic olefin as a repeating unit structure is particularly preferred.

As the polymer having a cyclic olefin as a repeating unit structure, a polymer having a structure to which only a repeating unit of a cyclic olefin structure is linked at an ethylene chain or a polymer having, in addition to the cyclic olefin structure, a structure in which ethylene or the derivative thereof is used as one of the repeating units can be preferably used. Specific examples of a film that can be used as the support including the polymer having a cyclic olefin as a repeating unit structure include ARTON (cyclic olefin polymer: COP) manufactured by JSR Corporation, ZEONOR (COP) manufactured by Zeon Corporation, TOPAS manufactured by Polyplastics Co., Ltd. (cyclic olefin copolymer: COC), APEL (COC) manufactured by Mitsui Chemicals, Inc., Fl film (COC) manufactured by Gunze Limited., and the like.

(Functional Layer)

As described above, the gas barrier film may include the functional layers on the barrier laminate or in other layers. The functional layers are described in detail in Paragraphs 0036 to 0038 of JP2006-289627A. Examples of functional layers other than the above-described functional layers include a matting agent layer, a protective layer, an antistatic layer, a levelling layer, an adhesiveness-improving layer, a light-shielding layer, an antireflection layer, a hard coat layer, a stress-relieving layer, an antifogging layer, an antifouling layer, a layer to be printed, an easy adhesion layer, and the like.

<Device>

The gas barrier film can be preferably used in a device having performance that is deteriorated due to chemical components (oxygen, water, a nitrogen oxide, a sulfur oxide, ozone, and the like) in the air. Examples of the device include electronic devices such as an organic EL element, a liquid crystal display element, a thin film transistor, a touch panel, electronic paper, a solar cell, and the gas barrier film is preferably used in an organic EL element.

The principal use of the gas barrier film is the sealing of an image display device or a flexible substrate and the gas barrier film can be preferably used, particularly, for the sealing of an organic EL device or an organic TFT device or a flexible substrate. One of the sealing forms is a solid sealing method and this form is a method in which a protective layer is formed on a device, then, an adhesive layer and the gas barrier film are laminated, and the components are cured. An adhesive is not particularly limited and examples thereof include a thermosetting epoxy resin, a photocurable acrylate resin, and the like.

Examples of the organic EL element in which the gas barrier film is used are described in JP2007-30387A.

### EXAMPLES

Hereinafter, the present invention will be more specifically described using examples. Materials, amounts used, fractions, treatment contents, treatment orders, and the like described in the following examples can be appropriately changed within the scope of the gist of the present invention. Therefore, the scope of the present invention is not limited to specific examples described below.

[Production of Gas Barrier Film]

A polymerizable composition including a polymerizable compound (93 parts by mass, manufactured by Shin-Nakamura Chemical Co., Ltd., A-DCP), a polymerization initiator (7 parts by mass, manufactured by Lamberti S.p.A., ESACURE KT046), and, as solvents, 2-butanone and propylene glycol 1-monomethylether 2-acetate was applied onto a cycloolefin polymer (COP) film (manufactured by JSR Corporation, ARTON, thickness: 70 μm, hereinafter, also referred to as “COP base material”) that served as the support so that the dried film thickness reached 2000 nm, thereby forming a film. The obtained film was cured by radiating an ultraviolet ray to the film under a nitrogen atmosphere having an oxygen content of 100 ppm or less at a radiation dose of 1 J/cm², thereby forming a first organic layer.

A silicon nitride film was formed on the surface of the first organic layer using a plasma CVD method so that the film thickness reached 40 nm.

Subsequently, a polymerizable composition including a polymerizable compound (68 parts by mass, manufactured by Toagosei Co., Ltd., TMPTA), a polymerizable compound having a phosphoric ester group (5 parts by mass, manufactured by Nippon Kayaku Co., Ltd., PM-21), a polymerizable compound having a silane coupling group (20 parts by mass, manufactured by Shin-Etsu Chemical Co., Ltd., KBM-5103), a polymerization initiator (7 parts by mass, manufactured by Lamberti S.p.A., ESACURE KTO46), and, as solvents, 2-butanone and propylene glycol 1-monomethylether 2-acetate was applied so that the dried film thickness reached 1000 nm, thereby forming a film. The obtained film was cured by radiating an ultraviolet ray to the film under a nitrogen atmosphere having an oxygen content of 100 ppm or less at a radiation dose of 1 J/cm², thereby forming a second organic layer. Therefore, a gas barrier film of Example 1 was obtained.

Furthermore, gas barrier films of Examples 2 to 4 and Comparative Examples 1 to 3 were obtained in the same manner as in Example 1 except that individual compounds described in Table 1 were used instead of the polymerizable compound (A-DCP) which was used to form the first organic layer in Example 1.

For the obtained gas barrier films, the adhesiveness and the moisture vapor transmission rate were measured using the following methods.

[Testing of Adhesiveness]

For the purpose of evaluating the adhesiveness between the COP base material and the barrier laminate, a cross-cut tape test according to JIS K5400 was carried out. Notches were made on the surface of the gas barrier film having the above-described layer constitution using a cutter at angles of 90 degrees and intervals of 1 mm, thereby producing 100 grids at intervals of 1 mm.

A 2 cm-wide mylar tape [manufactured by Nitto Denko Corporation, polyester tape (No. 31B), hereinafter, also referred to as “tape”] was attached to the film surface on which the grids were formed and the attached tape was peeled off using a tape peeling tester. The tape was attached and peeled off two more times, which made the number of times of the attachment and peeling of the tape reach three in total.

Out of the 100 grids on the gas barrier film, the number (n) of grids that remained without being peeled off was counted.

A: 100 grids

B: 60 grids to 99 grids

C: 0 grids to 59 grids

[Barrier Performance]

The moisture vapor transmission rate (g/m²/day) was measured using the method described in pp. 1435 to 1438 of SID Conference Record of the International Display Research Conference by G. Nisato, P. C. P. Bouten, and P. J. Slikkerveer. At this time, the temperature was set to 40° C. and the relative humidity was set to 90%. The barrier performance was evaluated as described below.

A: Less than 0.0005 g/m²/day

B: 0.0005 g/m²/day to 0.001 g/m²/day

C: More than 0.001 g/m2/day

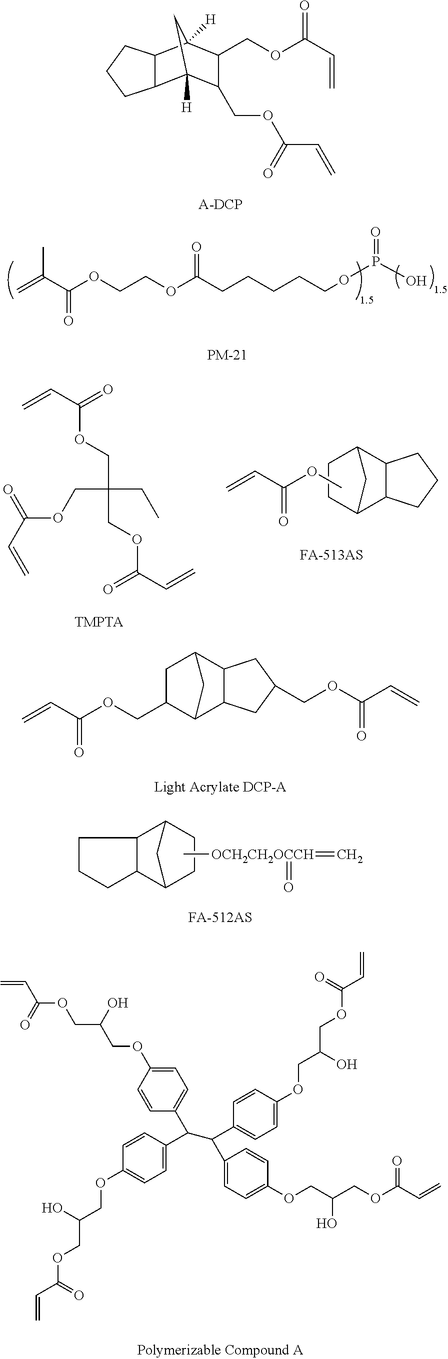

TABLE 1

| | 1st organic | Inorganic layer | | |
|---|---|---|---|---|
| | layer | Composition/ | Barrier | |
| | Polymerizable | film-forming | performance | Adhesive- |
| | compound | method | (g/m²/day) | ness |
| Example 1 | A-DCP | SiN/CVD | A | A |
| Example 2 | FA-513AS | SiN/CVD | A | A |
| Example 3 | DCP-A | SiN/CVD | A | B |
| Example 4 | FA-512AS | SiN/CVD | A | A |
| Comparative | TMPTA | SiN/CVD | C | C |
| Example 1 | | | | |
| Comparative | Polymerizable | SiN/CVD | B | C |
| Example 2 | compound A | | | |
| Comparative | Polymerizable | SiN/deposition | C | C |
| Example 3 | compound A | | | |

From the results described in Table 1, it is found that, when the polymerizable compound having the condensed polycyclic hydrocarbon structure unit in the first organic layer was used, the adhesiveness was ensured and the barrier performance was high.

In addition, films were produced in the same order using ZEONOR (COP) manufactured by Zeon Corporation, OPCON (COC) manufactured by Keiwa Inc., and APEL (COC) manufactured by Mitsui Chemicals, Inc. as the support instead of the ARTON film and the same evaluations were carried out for the obtained gas barrier films. As a result, the same effects could be obtained.

1. A barrier laminate comprising:
at least one organic layer; and at least one inorganic layer,
wherein the organic layer is a layer formed of a polymerizable composition including a polymerizable compound, and
the polymerizable compound includes 50% by mass or more of a condensed polycyclic hydrocarbon structure with respect to the total amount of polymerizable compounds.

2. The barrier laminate according to claim 1,
wherein the inorganic layer includes a metallic oxide or a metallic nitride.

3. The barrier laminate according to claim 1,
wherein the inorganic layer includes a silicon compound or an aluminum compound.

4. The barrier laminate according to claim 1,
wherein the polymerizable compound is a compound represented by General Formula (I) described below, 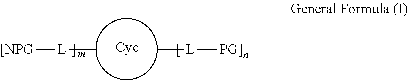
in the formula, Cyc represents a condensed polycyclic hydrocarbon residue, each of L's independently represents a single bond or a divalent linking group, PG represents a polymerizable group, in a case in which multiple PGs are present, each of the PGs independently represents a polymerizable group, NPG represents a non-polymerizable group, in a case in which multiple NPGs are present, each of the NPGs independently represents a non-polymerizable group, n is an integer selected from 1 to 4, and m is an integer selected from 0 to 4.

5. The barrier laminate according to claim 2,
wherein the polymerizable compound is a compound represented by General Formula (I) described below, 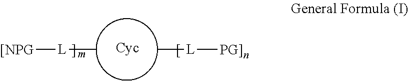
in the formula, Cyc represents a condensed polycyclic hydrocarbon residue, each of L's independently represents a single bond or a divalent linking group, PG represents a polymerizable group, in a case in which multiple PGs are present, each of the PGs independently represents a polymerizable group, NPG represents a non-polymerizable group, in a case in which multiple NPGs are present, each of the NPGs independently represents a non-polymerizable group, n is an integer selected from 1 to 4, and m is an integer selected from 0 to 4.

6. The barrier laminate according to claim 3,
wherein the polymerizable compound is a compound represented by General Formula (I) described below, 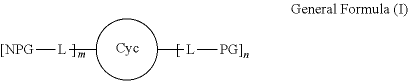
in the formula, Cyc represents a condensed polycyclic hydrocarbon residue, each of L's independently represents a single bond or a divalent linking group, PG represents a polymerizable group, in a case in which multiple PGs are present, each of the PGs independently represents a polymerizable group, NPG represents a non-polymerizable group, in a case in which multiple NPGs are present, each of the NPGs independently represents a non-polymerizable group, n is an integer selected from 1 to 4, and m is an integer selected from 0 to 4.

7. The barrier laminate according to claim 4,
wherein, in General Formula (1), n -L-PG groups are all bonded to one ring in the condensed polycyclic hydrocarbon structure.

8. The barrier laminate according to claim 4,
wherein the condensed polycyclic hydrocarbon residue is a residue obtained by removing (m+n) hydrogen atoms from any of condensed polycyclic hydrocarbons described below,

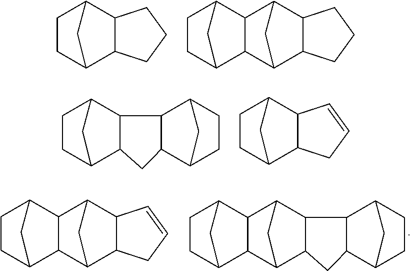

9. The barrier laminate according to claim 4,
wherein the condensed polycyclic hydrocarbon residue is a residue obtained by removing (m+n) hydrogen atoms from any of condensed polycyclic hydrocarbons described below,

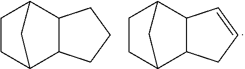

10. The barrier laminate according to claim 1,
wherein the inorganic layer is formed by chemical vapor deposition (CVD).

11. A gas barrier film including a polymer, comprising:
a support; and
the barrier laminate according to claim 1 provided on the support,
wherein the support includes a cyclic olefin as a repeating unit structure.

12. The gas barrier film according to claim 11,
wherein the support is in direct contact with at least one organic layer.

13. A device, comprising:
the gas barrier film according to claim 11 which is used as a substrate.

14. A device sealed using the gas barrier film according to claim 11.

15. The device according to claim 13, comprising:
an image display element.

16. A gas barrier film including a polymer, comprising:
a support; and
the barrier laminate according to claim 2 provided on the support,
wherein the support includes a cyclic olefin as a repeating unit structure.

17. A gas barrier film including a polymer, comprising:
a support; and
the barrier laminate according to claim 3 provided on the support,
wherein the support includes a cyclic olefin as a repeating unit structure.

18. A gas barrier film including a polymer, comprising:
a support; and
the barrier laminate according to claim 4 provided on the support,
wherein the support includes a cyclic olefin as a repeating unit structure.

19. A gas barrier film including a polymer, comprising:
a support; and
the barrier laminate according to claim 5 provided on the support,
wherein the support includes a cyclic olefin as a repeating unit structure.

20. A gas barrier film including a polymer, comprising:
a support; and
the barrier laminate according to claim 6 provided on the support,
wherein the support includes a cyclic olefin as a repeating unit structure.
